(19) United States
(12) Patent Application Publication
(10) Pub. No.: US 2007/0210426 A1
(43) Pub. Date: Sep. 13, 2007

(54) Gold-bumped interposer for vertically integrated semiconductor system

(76) Inventors: Mark A. Gerber, Lucas, TX (US); Wyatt A. Huddleston, Allen, TX (US)

Correspondence Address: TEXAS INSTRUMENTS INCORPORATED, P O BOX 655474, M/S 3999, DALLAS, TX, 75265, US

(21) Appl. No.: 11/370,265

(22) Filed: Mar. 7, 2006

(51) Int. Cl. H01L 23/02

(52) U.S. Cl. 257/678

(57) ABSTRACT

A semiconductor system (100) enabled by an interposer (101) with non-reflow metal studs (251), preferably gold, coated with reflow metals (252), preferably solder. The studs are on exit ports (220, 230, etc) of the interposer surface; selected exit ports may be spaced apart by less than 125 μm center to center. A first electrical device (102), such as one or more semiconductor chips with contact pads matching the locations of the interposer exit ports, contacts the studs on one interposer surface. A second electrical device (104), such as a semiconductor chip, a passive component, or both, is attached to the other interposer surface. A carrier (106) supports the first device and provides electrical connections (109) to external parts.

### FIELD OF THE INVENTION

The present invention is related in general to the field of semiconductor devices and processes, and more specifically to structure and processes of low profile packages for vertically integrated semiconductor systems.

### DESCRIPTION OF THE RELATED ART

The wide application of flip-chip assembly in the fabrication process flow of silicon integrated circuit (IC) devices is driven by several facts. First, the electrical performance of the semiconductor devices can be improved when the parasitic inductances correlated with conventional wire bonding interconnection techniques are reduced. Second, flip-chip assembly provides higher interconnection densities between chip and package than wire bonding. In particular, the absence of looped wires allows the reduction of package height (profile) in unison with thickness reductions of chips, leadframes, and encapsulations. Third, flip-chip assembly consumes less silicon “real estate” than wire bonding, and thus helps to conserve silicon area and reduce device cost. And fourth, the fabrication cost can be reduced, when concurrent gang-bonding techniques are employed rather than consecutive individual bonding steps.

The conventional fabrication process uses solder balls and their reflow characteristics as the standard method of ball bonding. While tin alloys have been widely accepted as materials for the solder balls, the contact pads of the IC chip have to receive special metallization for successful metallurgical attachment of the solder balls. Structure and preparation of metallizations and solder, as well as reliability aspects of the contacts, have been described in numerous publications. In known technology, however, the achievable bump pitch is limited. For solder materials, bumps or balls are presently limited to about 160 μm pitch center to center. These limits severely restrict the number of connections that can be made on the available chip surface, and thus constrain the use of flip-chip techniques, when devices with relatively small area chips are to be contacted.

For silicon chips, efforts were undertaken to replace reflow-based interconnecting balls with gold attached to aluminum-topped bond pads by a modified wire ball technique. In this technique, the bumps are allowed to retain a small “tail” which is formed when the gold wire is broken off after the free air ball has been formed and pressured as a “bump” against the substrate. The gold bump technique provides a substantially finer bump pitch; 25 μm diameter is the lower value for devices in production presently.

In later years, the substrates to which the IC chips are to be flip-bonded have been changed from ceramic to organic, such as printed circuit boards (for instance, FR-4) or a polyimide-based foil. Unchanged, however, is the traditional way of interconnecting the substrates to semiconductor chips by wire bonds or solder balls; it remains, therefore, difficult to scale substrates to the needs of small, chip-scale devices.

Recent applications especially for hand-held wireless equipments, combined with ambitious requirements for data volume and high processing speed, place new, stringent constraints on the size and volume of semiconductor components used for these applications. Consequently, there is a renewed push from the market place to shrink semiconductor devices both in two and in three dimensions, and this miniaturization effort includes packaging strategies for semiconductor devices and electronic systems.

### SUMMARY OF THE INVENTION

Applicants recognize the need for a fresh concept of achieving a coherent, low-cost method of assembling high lead count, yet chip-scale and low contour devices; the concept includes substrates and packaging methods for stacking devices. The goal should be vertically integrated semiconductor systems, which may include integrated circuit chips of functional diversity. The resulting system should have excellent electrical performance, mechanical stability, and high product reliability. Further, it will be a technical advantage that the fabrication method of the system is flexible enough to be applied for different semiconductor product families and a wide spectrum of design and process variations.

One embodiment of the invention is a semiconductor system enabled by an interposer with metal studs, which do not reflow at temperatures customarily used in silicon technology, preferably gold, and are coated with reflow metals, preferably solder. The studs are on input/output ports (exit) of the interposer surface; some exit ports may be spaced apart by less than 125 μm center to center. A first electrical device, such as one or more semiconductor chips with contact pads matching the locations of the interposer exit ports, contacts the studs on one interposer surface. Likewise, a second electrical device, such as a semiconductor chip, a passive component, or both, is attached the other interposer surface. A carrier supports the first device and provides electrical connections to external parts.

Another embodiment of the invention is an interposer for use in assembling semiconductor systems. The interposer has an electrically insulating sheet-like body with first and second surfaces and electrically conductive lines between the first and second surfaces. Electrically conductive paths extend through the insulating body from the first to the second surface; the paths have exit ports on the surfaces. Some ports may be spaced apart by less than 125 μm center to center. Non-reflow metal studs, preferably gold, coated with reflow metals, preferably solder, are attached to the ports.

Another embodiment of the invention is a method for fabricating a packaged semiconductor system. A sheet-like strip is provided, made of an electrically insulating material with first and second surfaces. The strip has electrically conductive lines between the first and second surfaces, and electrically conductive paths extending through the insulating body from the first to the second surface to surface, contacting the lines and having exit ports on the first surface. Some exit ports may be spaced apart by less than 125 μm center to center.

Non-reflow metal studs, preferably gold, are formed on the exit ports; the studs are coated with reflow metals, preferably solder. A device such as a chip, a passive component, or both, may be surface-mounted on the insulating body. Thereafter, the strip is singulated into discrete interposer units.

An electrically insulating carrier is then provided, which has a plurality of electrically conductive traces integral with the carrier and a plurality of electrically conductive vias extending through the carrier; the vias contact the traces and terminate in exit ports suitable for attaching metal reflow bodies.

An electrical device, preferably one or more semiconductor chips with contact pads located to match the locations of the exit ports on the first interposer surface, is attached and electrically connected to the carrier. The interposer exit ports are aligned with the matching device contact pads, and the pads are brought into contact with the metal studs on the ports.

The method may include the step of encapsulating the interposer, the devices, and at least portions of the carrier in protective material such as a polymer mold compound. The method may further include the step of attaching metal reflow bodies to the carrier exit ports.

The technical advances represented by certain embodiments of the invention will become apparent from the following description of the preferred embodiments of the invention, when considered in conjunction with the accompanying drawings and the novel features set forth in the appended claims.

### BRIEF DESCRIPTION OF THE DRAWINGS

FIG. 1 depicts a schematic cross section of a semiconductor system, vertically integrated by means of an interposer made of an electrically insulating body with non-reflow studs, coated by reflow metal, on its surfaces.

FIG. 2 is a magnified schematic cross section of a portion of an interposer made of an electrically insulating body with non-reflow studs, coated by reflow metal, on exit port of its surfaces.

FIG. 3 is a magnified schematic cross section of a portion of an interposer connected to a part, the connection enabled by a non-reflow stud coated with reflow metal.

FIG. 4 illustrates a schematic cross section of a semiconductor system, vertically integrated by means of an interposer made of an electrically insulating body with non-reflow studs, coated by reflow metal, on its surfaces.

FIG. 5 is a block diagram of the process flow for the fabrication of a packaged semiconductor system, which includes an interposer made of an electrically insulating body with non-reflow studs, coated with reflow metal, on its surfaces.

### DETAILED DESCRIPTION OF THE PREFERRED EMBODIMENTS

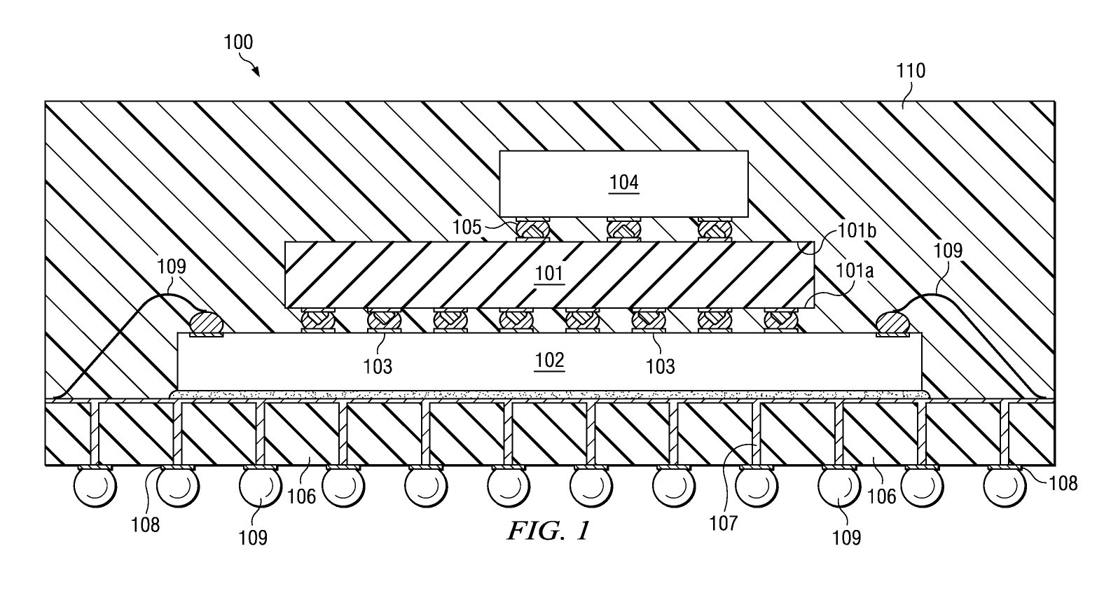

FIGS. 1 and 4 are examples of embodiments of the present invention, illustrating vertically integrated semiconductor systems, which are packaged in an encapsulation compound and, by means of solder bodies, prepared for connection to external parts. In FIG. 1, the system generally designated 100 has an interposer 101 made of an insulating body with first surface 101a and second surface 101b. Preferred materials for interposer 101 are ceramics or polymers in a sheet-like configuration; the polymers may be stiff or compliant. The interposers have typically a thickness in the range of about 50 to 500 μm.

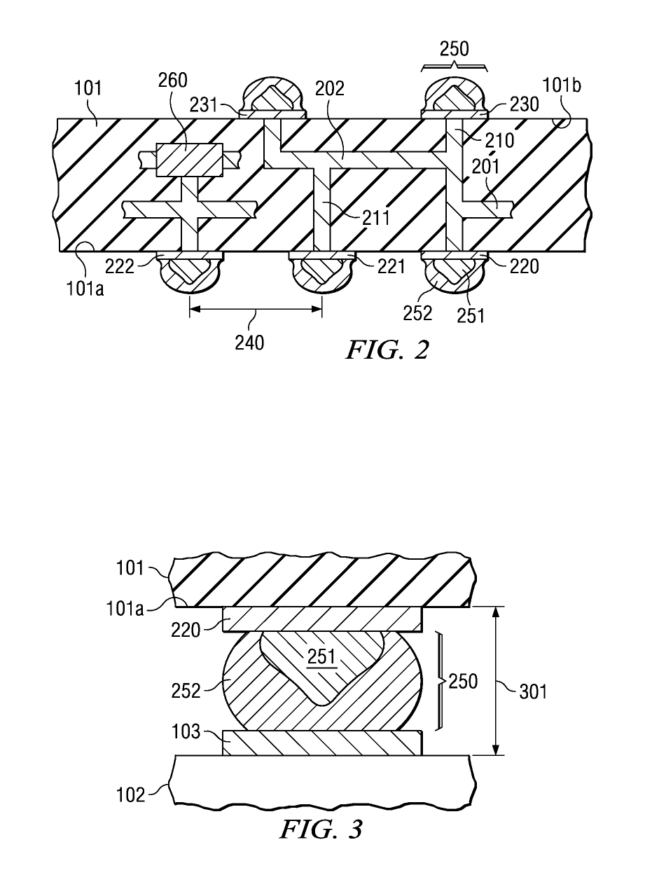

A portion of the interposer is magnified in FIG. 2 in order to show a plurality of electrically conductive lines 201, 202, etc., which are located between the first surface 101a and the second surface 101b of the interposer; the lines are patterned from sheets preferably made of copper or a copper alloy. The interposer further has a plurality of electrically conductive paths 210, 211, etc., which extend through the insulator from the first surface 101a to the second surface 101b. The paths may be in contact with selected lines and also have input/output terminals 220, 221, etc., at least on the first surface 101a. Input/output terminals are often referred to as “exit ports”. FIG. 2 also depicts exit ports 230, 231, etc., on the second surface 101b.

It is advantageous for many systems that interposer 101 includes passive electrical components 260 such as resistors and capacitors, which are integral with the insulator body and electrically connected to selected conductive paths 210.

The exist ports are preferably made of copper or a copper alloy, preferably with a surface covered by a thin layer of gold or palladium in order to facilitate bonding, welding, or soldering with other metals. The distance between ports can be designed according to the needs for interconnection. FIG. 2 illustrates the center-to-center distance 240 between adjacent exit ports 221 and 222. Selected exit ports may be spaced apart by less than 125 μm center-to-center.

As FIG. 2 shows, an electrical coupling member 250 is attached to each exit port. The coupling members 250 are made of a “non-reflow” metal stud 251 coated with reflow metals 252. “Non-reflow” metals have a melting temperature higher than the temperatures commonly employed in silicon technology, usually higher than about 900° C. The metal stud 251 is preferably gold, but may alternatively be made of copper with a gold surface, or copper/nickel/palladium. The reflow metal includes tin or a tin alloy, or any metal alloy suitable to act as solder.

The preferred method of creating stud 251 on the interposer exit port starts with a standard round wire of diameter between about 12 to 33 μm, preferably 18 to 25 μm. Preferably the wire consists of gold, with optional very small contents of beryllium, copper, palladium, iron, silver, calcium or magnesium to control the heat-affected and mechanically weak wire zone in ball formation. The interposer is positioned on a heated pedestal to raise the temperature to between 130 and 300° C. The wire is strung through the capillary of a bonder. At the tip of the wire, a free air ball. is created using either a flame or a spark technique. The ball has a typical diameter from about 1.2 to 1.6 wire diameters. The capillary is moved towards the interposer exit port 220 etc., lowered to touch the port, and the ball is pressed against the metallization of the port, creating an approximately hemispherical, flattened stud, which has an interface to the ports with an interdiffusion of metals for strong welding. The compression (also called Z- or mash) force is typically between about 17 and 75 g. At time of bonding, the temperature usually ranges from 140 to 270° C. The wire is broken off to release the capillary; the capillary may be lowered again to flatten any remaining wire stump.

The process of depositing the gold stud by a wire ball bond method highlights the advantages of depositing the stud on the interposer rather than on the semiconductor wafer. With the necessity of using low-k dielectrics in high-speed integrated circuits, which are known to be mechanically weak and sensitive to compressive and tensile stresses, it would be difficult to attach the gold stud on the chip bond pads with the required force without damaging the dielectric (for instance by cracking). In contrast, the interposer is relatively insensitive to mechanical force and impact.

An additional process advantage is that the interposer is preferably supplied in an elongated strip form, which simplifies the progression of the wire bonder operation. In contrast, the x-y progression of a semiconductor wafer is technically more complex and the wire bonder operation thus more demanding.

After the plurality of non-reflow studs on interposer surface 101a has been completed, a screen printing process is preferably employed to surround each stud with a layer of reflowable metal or metal alloy. The finished coupling members have an approximate shape as illustrated by the schematic cross sections of FIG. 2. The stud formation process described is repeated on interposer surface 101b, when the vertical integration of the semiconductor system calls for coupling members also on surface 101b. Alternatively, a technique including solder powder and flux may be employed.

Referring to FIG. 1, system 100 includes an electrical device 102, which has contact pads 103 located to match the locations of the exit ports on the first surface 101a of interposer 101. Preferably, contact pads 103 are made of copper with surface layers of nickel and palladium (or gold) so that pads 103 can be reliably contacted by reflow metal such as tin or a tin alloy (solder). As an example, device 102 may be one or more semiconductor integrated circuit chips with a large number of input/output (contact) pads. Selected pads may be spaced apart by less than 125 μm center to center.

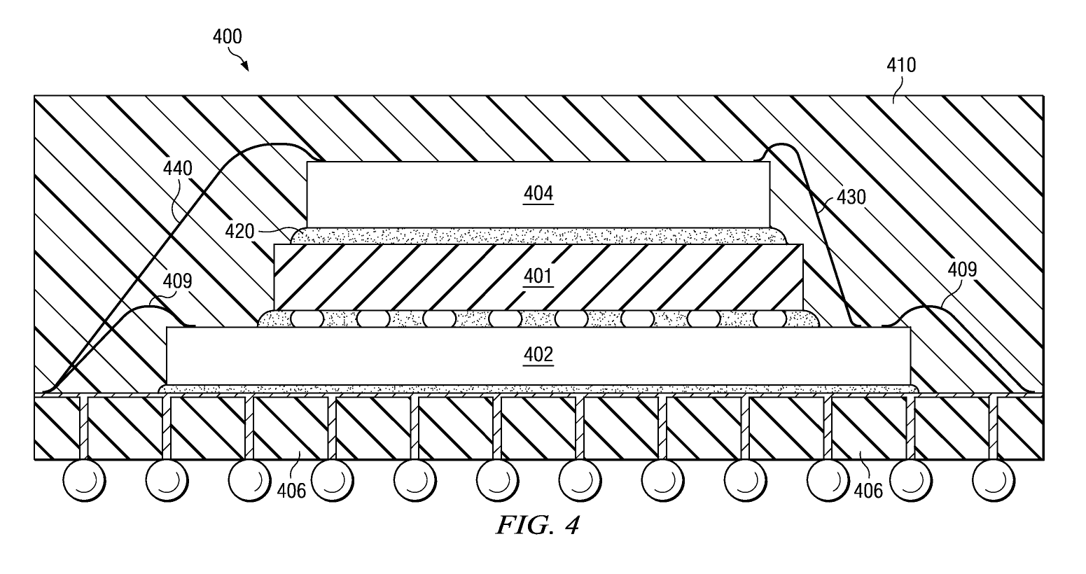

FIG. 3 depicts a contact pad 103 of device 102 after electrical contact has been established to exit port 220 of interposer 101. The contact is accomplished by the reflow metal 252 of the coupling member 250. The non-reflowing stud 251 serves as a spacing element of the contact, creating gap 301. As indicated in FIG. 1, gap 301 may be filled with molding compound; alternatively, it may be filled with a polymer-based underfill material to absorb thermo-mechanical stress.

Referring to FIG. 1, system 100 further includes a second electrical device 104. In FIG. 1, the second device has contact pads 105 located to match the locations of exit ports on the second surface 101b of interposer 101. The contact pads 105 of the second electrical device 104 are contacted by the interposer coupling members. In FIG. 4, the second device is attached to the second interposer surface by an adhesive; the device contact pads are wire bonded to contact pads of the first device or of the carrier. In other embodiments, there may be a combination of flip-attached and adhesive-attached second devices on the second interposer surface. The second electrical device may be one or more semiconductor chips, or one or more passive electrical components such as resistors or capacitors, or both a chip and a passive component.

As FIG. 1 illustrates, system 100 also includes an electrically insulating carrier 106, which has a plurality of electrically conductive traces (not shown in FIG. 1) between the carrier surfaces. Further, carrier 106 has a plurality of electrically conductive vias 107 extending through the carrier. Vias 107 may contact selected traces. Vias 107 also form exit ports 108 suitable for attaching metal reflow bodies 109.

The electrical device 102 is attached to carrier 106. In FIG. 1, an adhesive material is used for the attachment, and wire bonding 109 accomplishes the electrical connection. Alternatively, device 102 could be flipped onto carrier 106 using a surface mount technique, which also accomplishes the electrical connection.

The system 100 illustrated in FIG. 1 has encapsulation material to protect interposer 101, the first device 102, the second device 104, and at least portions of carrier 106. In particular, encapsulation material 110 protects the bonding wires 109. A system, in which no bonding wires are used and all parts are flipped and surface mounted, would not need encapsulation material 110. A preferred choice for material 110 is an epoxy-based molding compound as used in standard transfer molding technology. As pointed out in FIGS. 1 and 3, material 110 also fills the gaps between the assembled parts. In this fashion, it serves as an underfill material to reduce thermo-mechanical stress on the interconnecting joints 250.

Using the interposer of the invention, packaged systems with thin overall thickness can be fabricated. Including the carrier thickness, the reflow body diameters (solder balls), and the thickness of the mold compound above the top device, the package thickness may range from about 500 to 2000 μm with a preferred thickness of about 1200 μm. Included in these dimensions are the device thickness range from about 25 to 150 μm (preferred thickness about 100μ), the interposer thickness range from about 50 to 250 μm (preferred thickness about 100 μm), and the attach material thickness from about 12 to 75 μm (preferred thickness about 25 μm).

Another example of a vertically integrated semiconductor system 400, which employs a gold-bumped interposer 401, is illustrated in FIG. 4. Similar to the example in FIG. 1, interposer 401 has again an electrically insulating body with first and second surfaces, a plurality of electrically conductive lines between the first and the second surfaces, a plurality of electrically conductive paths extending through the insulating body from the first to the second surface, contacting the lines, and exit ports on the first surface. As depicted in FIGS. 2 and 3, non-reflow metal studs are attached to the exit ports and coated with reflow metals.

In the embodiment of FIG. 4, a first electrical device 402, shown as a semiconductor chip, has contact pads to match the locations of exit ports on the first interposer surface; the contact pads are contacted by the metal studs using the reflow metals. Furthermore, device 402 has bond pads suitable for wire bonding. In FIG. 4, these bond pads are used for attaching wire ball bonds and wire stitch bonds.

A second electrical device 404, exemplified in FIG. 4 as a semiconductor chip, is attached to interposer 401 using an adhesive material 420. Device 404 has contact pads suitable for wire bonding; some bonding wires 430 interconnect to first device 402, other bonding wires 440 interconnect to carrier 406. It should be stressed that in other systems device 404 may be one or more passive components, or a combination of one or more semiconductor chips and passive components.

In FIG. 4, an electrically insulating carrier 406 has a plurality of electrically conductive traces between the surfaces, and a plurality of electrically conductive vias extending through the carrier; the vias contact the traces and have exit ports suitable for attaching metal reflow bodies. The first electrical device 402 is attached and electrically connected to the carrier; the wire bonds are designated 409 in FIG. 4. Furthermore, the second device 404 is bonded by wires 440 to carrier 406.

Encapsulation material 410, preferably a molding compound, protects interposer 401, first device 402, second device 404, and portions of carrier 406, especially the bonding wires 409, 430, and 440.

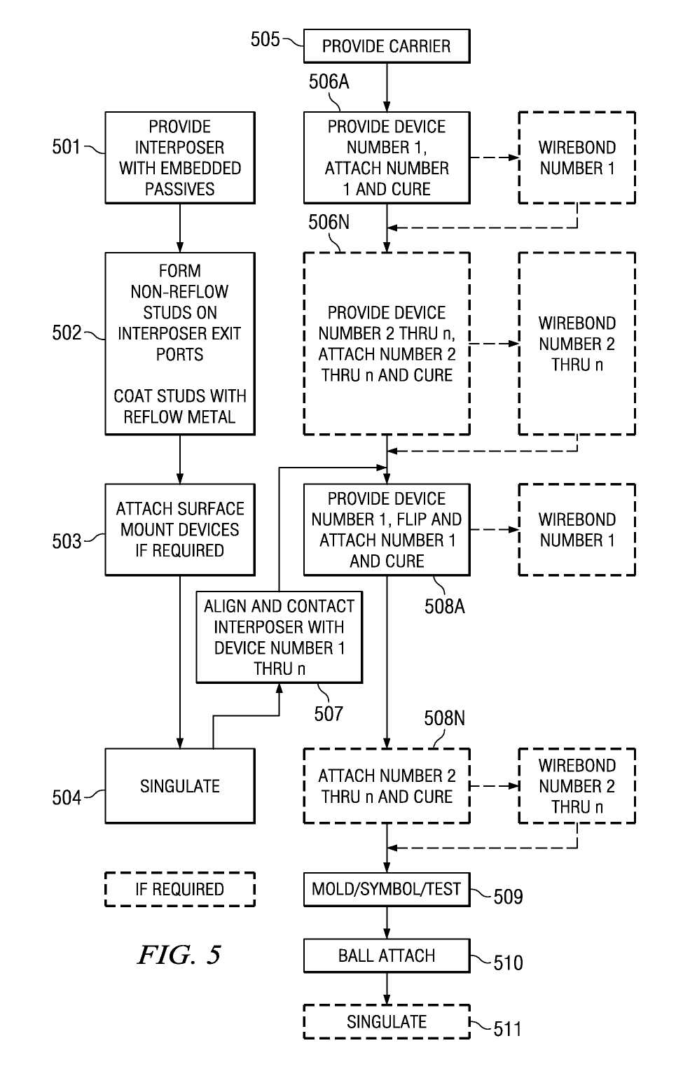

Another embodiment of the invention is a method for fabricating a packaged semiconductor system, especially a vertically integrated system. The block diagram of the method in FIG. 5 lists steps of the process flow. In step 501, a strip of an electrically insulating sheet-like body with a first and a second surface is provided. The body has a plurality of electrically conductive lines between the first and the second surfaces; further, a plurality of electrically conductive paths extend from the first to the second surface, contacting the lines and exit ports on the surfaces. If required, passive electrical components such as resistors and capacitors are included in the insulator body and connected to the conductive paths (see FIG. 2).

In step 502, non-reflow metal studs are formed on the exit ports. A preferred process uses ball bonding (preferably gold) and subsequent breaking of the wire; an alternative batch process uses electroless plating. While the preferred stud metal is gold, alternative studs may be made of copper or copper/nickel/palladium. The non-reflow studs are then coated with reflow metals such as tin or tin alloy, preferably using a screen printing process; alternatively, a process including solder powder and flux may be used.

If required by the system-to-be-fabricated, step 503 involves the surface mounting of an electronic device on the exit ports on the second surface of the insulating interposer body. This device may be one or more semiconductor chips, one or more passive components, or both. To perform this attachment step, while the interposer is still available as a strip, offers manufacturing advantages for high throughput and tight process control. An example resulting from this process step is shown in FIG. 1, illustrating flip-device 104. Alternatively, the second device may be attached by an adhesive on the second interposer surface.

The interposer strip is singulated in step 504 into discrete interposer units. The subsequent process steps use the interposer in discrete units.

Step 505 provides an electrically insulating carrier having a plurality of electrically conductive traces integral with the carrier and a plurality of electrically conductive vias extending through the carrier. The vias are contacting the traces and having exit ports suitable for attaching metal reflow bodies.

In step 506A, an electrical device (designated #1 in FIG. 5) is provided, which has contact pads to match the locations of the exit ports on the first interposer surface. The device may be one or more semiconductor chips. The device is attached and electrically attached to the carrier. The attachment step is preferably performed by wire bonding, as indicated in FIG. 5 by the dashed outline of the process block, or it may alternatively be performed by a flip-chip process.

Process step 506A—providing devices, attaching devices to the carrier and curing the attach material, and wirebonding devices—may be repeated several times (2 through n times). This option is indicated by step 506N in FIG. 5, in dashed outline of the blocks (in FIGS. 1 and 4, only a single chip is illustrated, designated 102 and 402, respectively).

In process step 507, the interposer is flipped and the exit ports aligned with the matching device contact pads; thereafter, the pads are brought in contact with the metal studs on the ports to achieve metallic attachment.

In step 508A, another electrical device (designated #1 in FIG. 5) is provided, which is attached by an adhesive to the second interposer surface. The device may be one or more semiconductor chips. After curing the adhesive, the device is electrically connected to the carrier and/or to the device attached in process step 506A. The attachment step is performed by wire bonding, as indicated in FIG. 5 by the dashed outline of the process block. If the attachment is alternatively performed by a flip-chip process, it may be preferable to perform the attachment process already in conjunction with step 503.

Process step 508A—providing devices, attaching devices to the interposer and curing the attach material, and wire-bonding devices—may be repeated several times (2 through n times). This option is indicated by step 508N in FIG. 5, in dashed outline of the blocks (in FIG. 4, only a single chip is illustrated, designated 404).

Block 509 combines the process steps of encapsulating, symbolizing, and testing. The encapsulation step, preferably performed by transfer molding a mold compound, protects the interposer, the devices, and at least portions of the carrier in protective material.

Block 510 addresses the step of attaching metal reflow bodies, preferably solder balls, to the carrier exit ports.

The final block 511 is shown in dashed outline in FIG. 5 to indicate that the singulation step is called for only when either the molding step was performed as a batch process, or the singulation of the interposer in step 504 has been postponed to step 511.

While this invention has been described in reference to illustrative embodiments, this description is not intended to be construed in a limiting sense. Various modifications and combinations of the illustrative embodiments, as well as other embodiments of the invention, will be apparent to persons skilled in the art upon reference to the description. As an example, the invention applies to products using any type of semiconductor chip, discrete or integrated circuit, and the material of the semiconductor chip may comprise silicon, silicon germanium, gallium arsenide, or any other semiconductor or compound material used in integrated circuit manufacturing.

As another example, the process step of encapsulating can be omitted when the integration of the system has been achieved by flip-chip assembly.

It is therefore intended that the appended claims encompass any such modifications or embodiment.

We claim:

1. A semiconductor system comprising:
an interposer having an electrically insulating body with a first and a second surface, a plurality of electrically conductive lines between the first and the second surfaces, a plurality of electrically conductive paths extending through the insulating body from the first to the second surface, contacting the lines, and having exit ports on the first surface;
a non-reflow metal stud attached to the exit ports, coated with reflow metals;
a first electrical device having contact pads to match the locations of exit ports on the first interposer surface, the contact pads contacted by the metal studs;
a second electrical device attached to the second interposer surface;
an electrically insulating carrier having a plurality of electrically conductive traces between the surfaces, and a plurality of electrically conductive vias extending through the carrier, the vias contacting the traces and having exit ports suitable for attaching metal reflow bodies; and
the first electrical device attached and electrically connected to the carrier.

2. The system according to claim 1 wherein the interposer further includes passive electrical components integral with the insulator body and connected to selected conductive paths.

3. The system according to claim 1 wherein the first electrical device is one or more semiconductor chips having bond pads.

4. The system according to claim 1 wherein the second electrical device is one or more semiconductor chips having bond pads.

5. The system according to claim 1 wherein the second electrical device is one or more passive components.

6. The system according to claim 1 wherein the second electrical device has contact pads to match the locations of the exit ports on the second interposer surface, and is attached by establishing contact between the pads and the metal studs.

7. The system according to claim 2 wherein the second electrical device is attached to the second interposer surface by an adhesive, and the device contact pads are wire bonded to contact pads of the first device or of the carrier.

8. The system according to claim 1 wherein exit ports are spaced apart by less than 125 μm center to center.

9. The system according to claim 1 further including a metal reflow body attached to the carrier exit ports.

10. The system according to claim 1 wherein the non-reflow metal studs include gold studs, copper studs with gold surface, or copper/nickel/palladium studs.

11. The system according to claim 1 further having encapsulation material protecting the interposer, the first and second devices, and at least portions of the carrier.

12. An interposer for use in assembling semiconductor systems, comprising:
an electrically insulating sheet-like body having a first and a second surface, a plurality of electrically conductive lines between the first and the second surfaces, a plurality of electrically conductive paths extending through the insulating body from the first to the second surface, contacting the lines and having exit ports on the first surface; and
a non-reflow metal stud attached to the exit ports, coated with reflow metals.

13. The interposer according to claim 12 further including passive electrical components integral with the insulator body and connected to selected conductive paths.

14. The interposer according to claim 12 wherein exit ports are spaced apart by less than 125 μm center to center.

15. The interposer according to claim 12 wherein the non-reflow metal studs include gold studs, copper studs with gold surface, or copper/nickel/palladium studs.

16. A method for fabricating a packaged semiconductor system, comprising the steps of:
providing a strip of an electrically insulating sheet-like body with a first and a second surface, a plurality of electrically conductive lines between the first and the second surfaces, a plurality of electrically conductive paths extended from the first to the second surface, contacting the lines, and having exit ports on the first surface;
forming non-reflow metal studs on the exit ports;
coating the studs with reflow metals;
singulating the strip into discrete interposer units;
providing an electrically insulating carrier having a plurality of electrically conductive traces integral with the carrier and a plurality of electrically conductive vias extending through the carrier, the vias contacting the traces and having exit ports suitable for attaching metal reflow bodies;
providing an electrical device having contact pads to match the locations of the exit ports on the first interposer surface;
attaching and electrically connecting the electrical device to the carrier; and
aligning the interposer exit ports with the matching device contact pads, and bringing the pads in contact with the metal studs on the ports.

17. The method according to claim 16 further including the step of encapsulating the interposer, the devices, and at least portions of the carrier in protective material.

18. The method according to claim 16 further including the step of attaching metal reflow bodies to the carrier exit ports.

19. The method according to claim 16 further including the step of surface-mounting a chip, a passive component, or both, on the exit ports of the second surface of the insulating body, the step of surface-mounting performed after the step of coating the studs and before the step of singulating the strip.

20. The method according to claim 16 wherein the insulating body further includes passive electrical components integral with the insulator body and connected to selected conductive paths.
